(19) United States
(12) Patent Application Publication
(10) Pub. No.: US 2017/0365567 A1
(43) Pub. Date: Dec. 21, 2017

(54) FAN-OUT SEMICONDUCTOR PACKAGE

(71) Applicant: SAMSUNG ELECTRO-MECHANICS CO., LTD., Suwon-si (KR)

(72) Inventors: Yun Bog KIM, Suwon-si (KR); Mi Jin PARK, Suwon-si (KR); Yeon Seop YU, Suwon-si (KR); Shang Hoon SEO, Suwon-si (KR)

(21) Appl. No.: 15/369,518

(22) Filed: Dec. 5, 2016

(30) Foreign Application Priority Data
Jun. 20, 2016 (KR) 10-2016-0076913
Aug. 24, 2016 (KR) 10-2016-0107743

(51) Int. Cl. H01L 23/00; H01L 23/31; H01L 23/538

(52) U.S. Cl. CPC H01L 24/05; H01L 23/5383; H01L 23/5384; H01L 23/5386; H01L 23/5389; H01L 23/3114; H01L 2224/05664; H01L 2224/05663; H01L 2224/05647; H01L 2224/05644; H01L 2224/05639; H01L 2224/05569; H01L 2224/0401; H01L 2224/05666; H01L 2224/05669; H01L 2224/05671; H01L 2224/05673; H01L 2224/05678; H01L 2224/05676

(57) ABSTRACT

A fan-out semiconductor package includes: a first interconnection member having a through-hole; a semiconductor chip disposed in the through-hole and having an active surface and an inactive surface; an encapsulant encapsulating at least portions of the first interconnection member and the inactive surface of the semiconductor chip; and a second interconnection member disposed on the first interconnection member and the active surface of the semiconductor chip, wherein the first interconnection member and the second interconnection member each include a redistribution layer electrically connected to the connection pads, the semiconductor chip includes a passivation layer having openings exposing at least portions of the connection pads, the redistribution layer of the second interconnection member is connected to the connection pad through a via, a metal layer is disposed between the connection pad and the via, and the metal layer covers at least a portion of the connection pad.

### CROSS-REFERENCE TO RELATED APPLICATION(S)

This application claims the benefit of priority to Korean Patent Application Nos. 10-2016-0076913, filed on Jun. 20, 2016; and 10-2016-0107743, filed on Aug. 24, 2016 in the Korean Intellectual Property Office, the entire disclosures of which are incorporated herein by reference.

### TECHNICAL FIELD

The present disclosure relates to a semiconductor package, and more particularly, to a fan-out semiconductor package in which connection terminals may be extended outwardly of a region in which a semiconductor chip is disposed.

### BACKGROUND

Recently, a significant recent trend in the development of technology related to semiconductor chips has been to reduce the size of semiconductor chips. Therefore, in the field of package technology, in accordance with a rapid increase in demand for small-sized semiconductor chips, or the like, there has been increased demand for a semiconductor package having a compact size while including a plurality of pins.

One type of package technology suggested to satisfy the technical demand as described above is a fan-out package. Such a fan-out package has a compact size and may allow a plurality of pins to be implemented by redistributing connection terminals outwardly of a region in which the semiconductor chip is disposed.

### SUMMARY

An aspect of the present disclosure provides a fan-out semiconductor package in which corrosion of a connection pad that may occur due to various causes may be prevented.

According to an aspect of the present disclosure, a fan-out semiconductor package is provided, in which a metal layer is formed on an exposed surface of a connection pad to prevent corrosion of the connection pad.

According to an aspect of the present disclosure, a fan-out semiconductor package includes: a first interconnection member having a through-hole; a semiconductor chip disposed in the through-hole of the first interconnection member and having an active surface having connection pads disposed thereon and an inactive surface opposing the active surface; an encapsulant encapsulating at least portions of the first interconnection member and the inactive surface of the semiconductor chip; and a second interconnection member disposed on the first interconnection member and the active surface of the semiconductor chip, wherein the first interconnection member and the second interconnection member include, respectively, redistribution layers electrically connected to the connection pads, the semiconductor chip includes a passivation layer having openings exposing at least portions of the connection pads, the redistribution layer of the second interconnection member is connected to the connection pad through a via, a metal layer is disposed between the connection pad and the via, and the metal layer covers at least a portion of the connection pad.

### BRIEF DESCRIPTION OF THE DRAWINGS

The above and other aspects, features, and advantages of the present disclosure will be more clearly understood from the following detailed description taken in conjunction with the accompanying drawings, in which:

FIG. 1 is a schematic block diagram illustrating an example of an electronic device system;

FIG. 2 is a schematic perspective view illustrating an example of an electronic device;

FIGS. 3A and 3B are schematic cross-sectional views illustrating states of a fan-in semiconductor package before and after being packaged;

FIG. 4 is schematic cross-sectional views illustrating a packaging process of a fan-in semiconductor package;

FIG. 5 is a schematic cross-sectional view illustrating a case in which a fan-in semiconductor package is mounted on an interposer substrate and is finally mounted on a main board of an electronic device;

FIG. 6 is a schematic cross-sectional view illustrating a case in which a fan-in semiconductor package is embedded in an interposer substrate and is finally mounted on a main board of an electronic device;

FIG. 7 is a schematic cross-sectional view illustrating a fan-out semiconductor package;

FIG. 8 is a schematic cross-sectional view illustrating a case in which a fan-out semiconductor package is mounted on a main board of an electronic device;

FIG. 9 is a schematic cross-sectional view illustrating an example of a fan-out semiconductor package;

FIG. 10 is a schematic plan view taken along line I-I′ of the fan-out semiconductor package of FIG. 9;

FIG. 11 is a schematic enlarged view illustrating region A of the fan-out semiconductor package of FIG. 9;

FIG. 12 is a schematic enlarged view illustrating a modified example of region A of the fan-out semiconductor package of FIG. 9;

FIG. 13 is schematic views illustrating an example of processes of manufacturing region A of FIGS. 11 and 12;

FIG. 14 is a schematic cross-sectional view illustrating another example of a fan-out semiconductor package;

FIG. 15 is a schematic plan view taken along line II-II′ of the fan-out semiconductor package of FIG. 14;

FIG. 16 is a schematic enlarged view illustrating region B of the fan-out semiconductor package of FIG. 14;

FIG. 17 is a schematic enlarged view illustrating a modified example of region B of the fan-out semiconductor package of FIG. 14;

FIG. 18 is schematic views illustrating an example of processes of manufacturing region B of FIGS. 16 and 17;

FIG. 19 is a schematic cross-sectional view illustrating another example of a fan-out semiconductor package;

FIG. 20 is a schematic cross-sectional view illustrating another example of a fan-out semiconductor package;

FIG. 21 is a schematic view illustrating a case in which corrosion occurs on a connection pad;

FIG. 22 is a schematic view illustrating corrosion of a connection pad in a state in which a voltage is not applied; and

FIG. 23 is a schematic view illustrating corrosion of a connection pad in a state in which a voltage is applied.

### DETAILED DESCRIPTION

Hereinafter, exemplary embodiments in the present disclosure will be described with reference to the accompanying drawings. In the accompanying drawings, shapes, sizes, and the like, of components may be exaggerated or shortened for clarity.

The term “an exemplary embodiment” used herein does not refer to the same exemplary embodiment, and is provided to emphasize a particular feature or characteristic different from that of another exemplary embodiment. However, exemplary embodiments provided herein are considered to be able to be implemented by being combined in whole or in part one with another. For example, one element described in a particular exemplary embodiment, even if it is not described in another exemplary embodiment, may be understood as a description related to another exemplary embodiment, unless an opposite or contradictory description is provided therein.

The meaning of a “connection” of a component to another component in the description includes an indirect connection through a third component as well as a direct connection between two components. In addition, “electrically connected” means the concept including a physical connection and a physical disconnection. It can be understood that when an element is referred to with “first” and “second”, the element is not limited thereby. They may be used only for a purpose of distinguishing the element from the other elements, and may not limit the sequence or importance of the elements. In some cases, a first element may be referred to as a second element without departing from the scope of the claims set forth herein. Similarly, a second element may also be referred to as a first element.

Herein, an upper portion, a lower portion, an upper side, a lower side, an upper surface, a lower surface, and the like, are decided in the attached drawings. For example, a first interconnection member is disposed on a level above a redistribution layer. However, the claims are not limited thereto. In addition, a vertical direction refers to the abovementioned upward and downward directions, and a horizontal direction refers to a direction perpendicular to the abovementioned upward and downward directions. In this case, a vertical cross section refers to a case taken along a plane in the vertical direction, and an example thereof may be a cross-sectional view illustrated in the drawings. In addition, a horizontal cross section refers to a case taken along a plane in the horizontal direction, and an example thereof may be a plan view illustrated in the drawings.

Terms used herein are used only in order to describe an exemplary embodiment rather than limiting the present disclosure. In this case, singular forms include plural forms unless interpreted otherwise in context.

Electronic Device

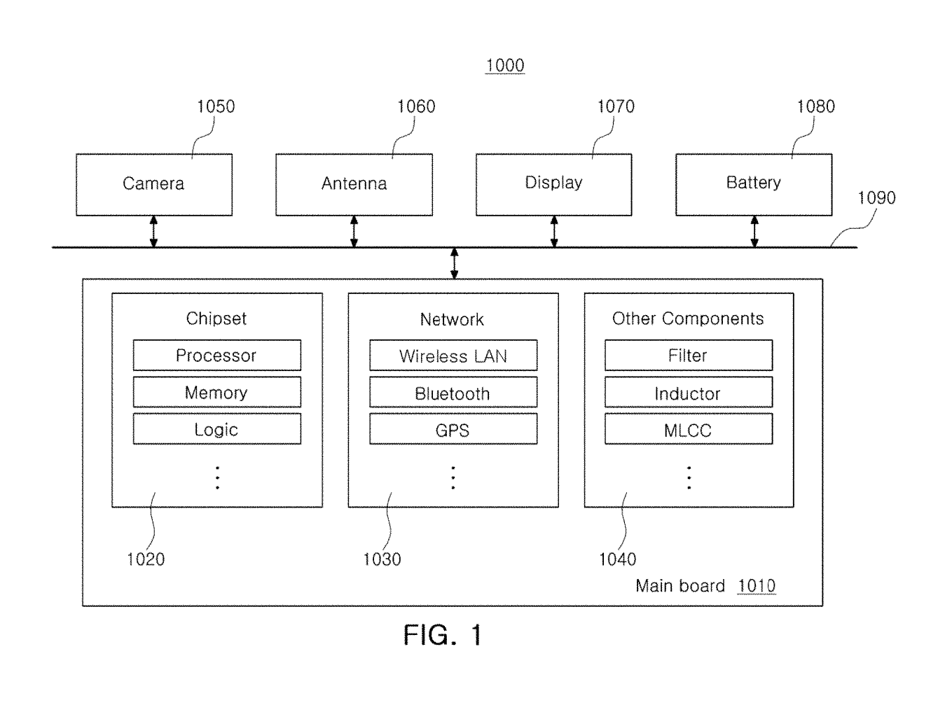

FIG. 1 is a schematic block diagram illustrating an example of an electronic device system.

Referring to FIG. 1, an electronic device 1000 may accommodate a mother board 1010 therein. The mother board 1010 may include chip-related components 1020, network-related components 1030, other components 1040, and the like, physically or electrically connected thereto. These components may be connected to others to be described below to form various signal lines 1090.

The chip-related components 1020 may include a memory chip such as a volatile memory (for example, a dynamic random access memory (DRAM)), a non-volatile memory (for example, a read only memory (ROM)), a flash memory, or the like; an application processor chip such as a central processor (for example, a central processing unit (CPU)), a graphics processor (for example, a graphics processing unit (GPU)), a digital signal processor, a cryptographic processor, a microprocessor, a microcontroller, or the like; and a logic chip such as an analog-to-digital (ADC) converter, an application-specific integrated circuit (ASIC), or the like. However, the chip-related components 1020 are not limited thereto, but may also include other types of chip related components. In addition, the chip-related components 1020 may be combined with each other.

The network-elated components 1030 may include protocols such as wireless fidelity (Wi-Fi) (Institute of Electrical And Electronics Engineers (IEEE) 802.11 family, or the like), worldwide interoperability for microwave access (WiMAX) (IEEE 802.16 family, or the like), IEEE 802.20, long term evolution (LTE), evolution data only (Ev-DO), high speed packet access+(HSPA+), high speed downlink packet access+(HSDPA+), high speed uplink packet access+(HSUPA+), enhanced data GSM environment (EDGE), global system for mobile communications (GSM), global positioning system (GPS), general packet radio service (GPRS), code division multiple access (CDMA), time division multiple access (TDMA), digital enhanced cordless telecommunications (DECT), Bluetooth, 3G, 4G, and 5G protocols, and any other wireless and wired protocols designated after the abovementioned protocols. However, the network-related components 1030 are not limited thereto, but may also include a variety of other wireless or wired standards or protocols. In addition, the network-related components 1030 may be combined with each other, together with the chip related components 1020 described above.

Other components 1040 may include a high frequency inductor, a ferrite inductor, a power inductor, ferrite beads, a low temperature co-fired ceramic (LTCC), an electromagnetic interference (EMI) filter, a multilayer ceramic capacitor (MLCC), or the like. However, other components 1040 are not limited thereto, but may also include passive components used for various other purposes, or the like. In addition, other components 1040 may be combined with each other, together with the chip related components 1020 or the network related components 1030 described above.

Depending on a type of the electronic device 1000, the electronic device 1000 may include other components that may or may not be physically or electrically connected to the mother board 1010. These other components may include, for example, a camera module 1050, an antenna 1060, a display device 1070, a battery 1080, an audio codec (not illustrated), a video codec (not illustrated), a power amplifier (not illustrated), a compass (not illustrated), an accelerometer (not illustrated), a gyroscope (not illustrated), a speaker (not illustrated), a mass storage unit (for example, a hard disk drive) (not illustrated), a compact disk (CD) drive (not illustrated), a digital versatile disk (DVD) drive (not illustrated), or the like. However, these other components are not limited thereto, but may also include other components used for various purposes depending on a type of electronic device 1000, or the like.

The electronic device 1000 may be a smartphone, a personal digital assistant (PDA), a digital video camera, a digital still camera, a network system, a computer, a monitor, a tablet PC, a laptop PC, a netbook PC, a television, a video game machine, a smartwatch, an automotive component, or the like. However, the electronic device 1000 is not limited thereto, and may be any other electronic device processing data.

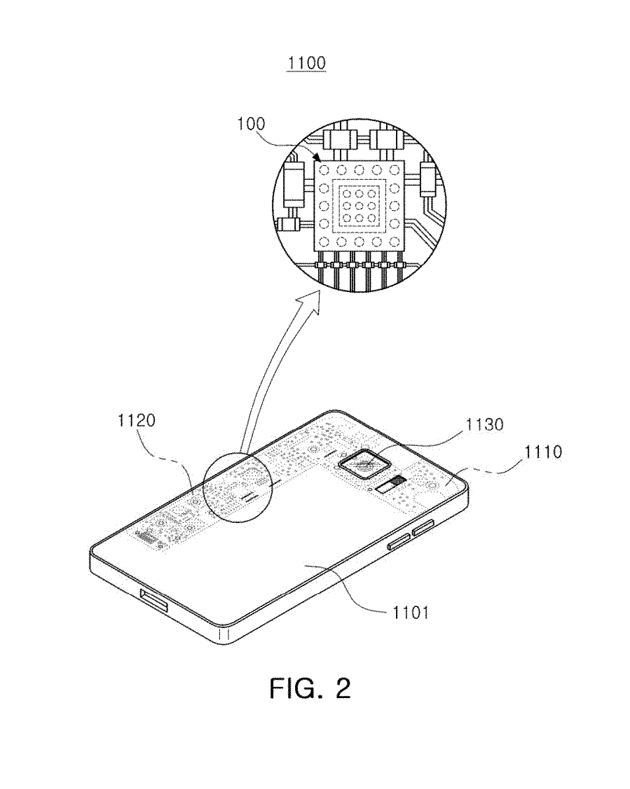

FIG. 2 is a schematic perspective view illustrating an example of an electronic device.

Referring to FIG. 2, a semiconductor package may be used for various purposes in the various electronic devices 1000 as described above. For example, a main board 1110 may be accommodated in a body 1101 of a smartphone 1100, and various electronic components 1120 may be physically or electrically connected to the main board 1110. In addition, other components that may or may not be physically or electrically connected to the main board 1110, such as the camera module 1050, may be accommodated in the body 1101. Some of the electronic components 1120 may be the chip related components, and the semiconductor package 100 may be, for example, an application processor among the chip related components, but is not limited thereto. The electronic device is not necessarily limited to the smartphone 1100, but may be other electronic devices as described above.

Semiconductor Package

Generally, numerous fine electrical circuits are integrated in a semiconductor chip. However, the semiconductor chip may not serve as a finished semiconductor product in itself to avoid damage due to external physical or chemical impacts. Therefore, the semiconductor chip itself may not be used in a bare state, but may be packaged and used in an electronic device, or the like, in a packaged state.

In addition, semiconductor packaging may be beneficial due to the existence of a difference in a circuit width between the semiconductor chip and a main board of the electronic device in terms of electrical connections. In detail, a size of connection pads of the semiconductor chip and an interval between the connection pads of the semiconductor chip are very fine, but a size of component mounting pads of the main board used in the electronic device and an interval between the component mounting pads of the main board are significantly larger than those of the semiconductor chip. Therefore, it may be difficult to directly mount the semiconductor chip on the main board, and packaging technology for buffering a difference in a circuit width between the semiconductor chip and the main board is required.

A semiconductor package manufactured by the packaging technology may be classified as a fan-in semiconductor package or a fan-out semiconductor package depending on a structure and a purpose thereof.

The fan-in semiconductor package and the fan-out semiconductor package will hereinafter be described in more detail with reference to the drawings.

Fan-in Semiconductor Package

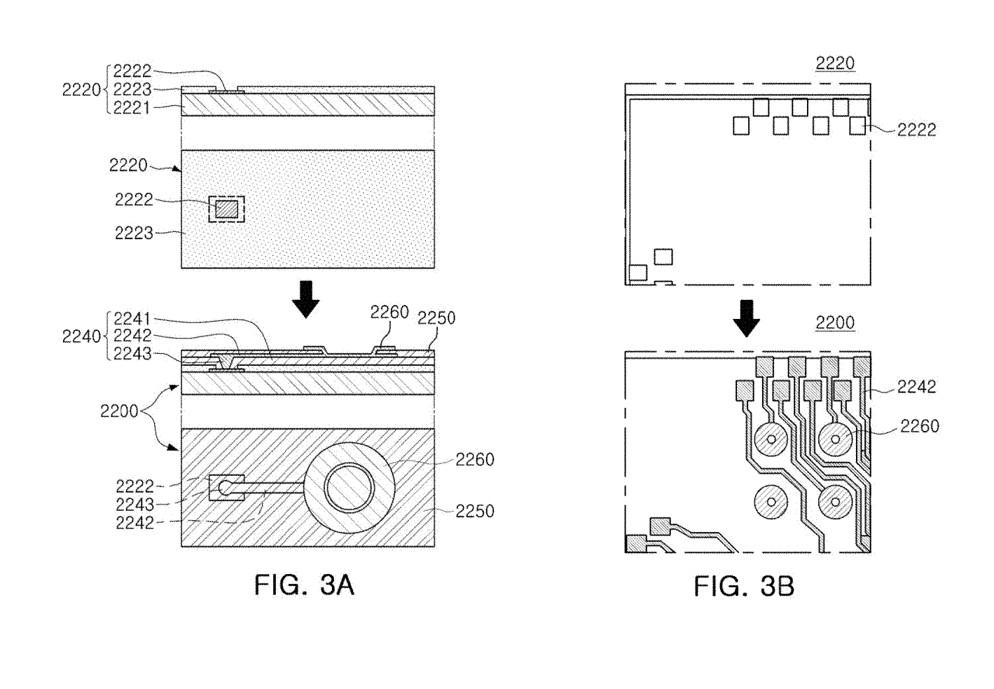

FIGS. 3A and 3B are schematic cross-sectional views illustrating states of a fan-in semiconductor package before and after being packaged.

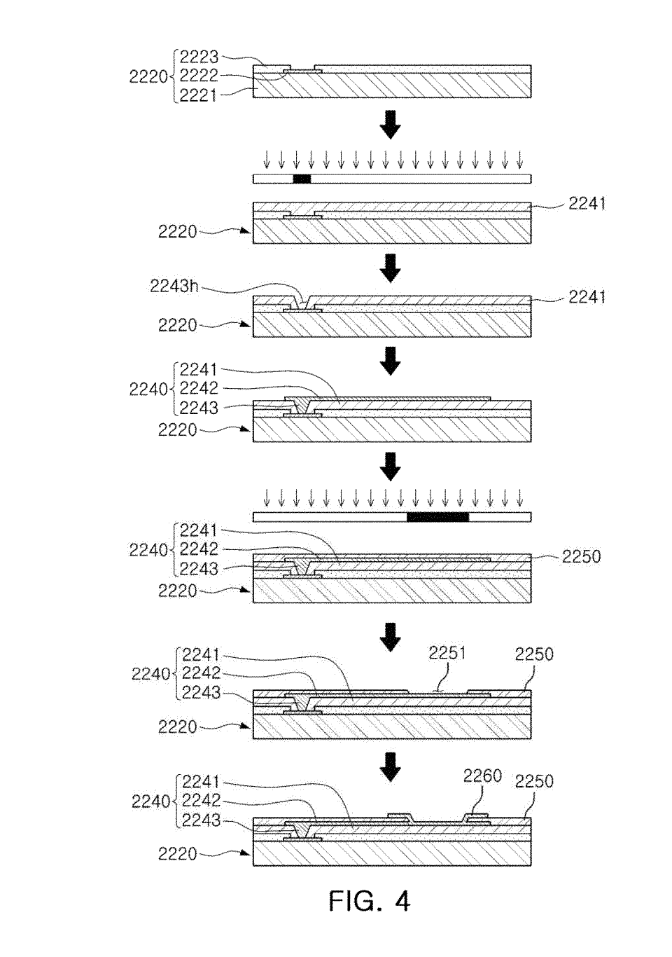

FIG. 4 is schematic cross-sectional views illustrating a packaging process of a fan-in semiconductor package.

Referring to the drawings, a semiconductor chip 2220 may be, for example, an integrated circuit (IC) in a bare state, including a body 2221 including silicon (Si), germanium (Ge), gallium arsenide (GaAs), or the like, connection pads 2222 formed on one surface of the body 2221 and including a conductive material such as aluminum (Al), or the like, and a passivation layer 2223 such as an oxide film, a nitride film, or the like, formed on one surface of the body 2221 and covering at least portions of the connection pads 2222. In this case, since the connection pads 2222 are significantly small, it is difficult to mount the integrated circuit (IC) on an intermediate level printed circuit board (PCB) as well as on the main board of the electronic device, or the like.

Therefore, an interconnection member 2240 may be formed depending on a size of the semiconductor chip 2220 on the semiconductor chip 2220 in order to redistribute the connection pads 2222. The interconnection member 2240 may be formed by forming an insulating layer 2241 on the semiconductor chip 2220 using an insulating material such as a photoimagable dielectric (PID) resin, forming via holes 2243h opening the connection pads 2222, and then forming wiring patterns 2242 and vias 2243. Then, a passivation layer 2250 protecting the interconnection member 2240 may be formed, an opening 2251 may be formed, and an under-bump metal layer 2260, or the like, may be formed. That is, a fan-in semiconductor package 2200 including, for example, the semiconductor chip 2220, the interconnection member 2240, the passivation layer 2250, and the under-bump metal layer 2260 may be manufactured through a series of processes.

As described above, the fan-in semiconductor package may have a package form in which all of the connection pads, for example, input/output (I/O) terminals, of the semiconductor chip are disposed inside the semiconductor chip, and may have excellent electrical characteristics and be produced at a low cost. Therefore, many elements mounted in smartphones have been manufactured in a fan-in semiconductor package form. In detail, many elements mounted in smartphones have been developed to implement a rapid signal transfer while having a compact size.

However, since all I/O terminals need to be disposed inside the semiconductor chip in the fan-in semiconductor package, the fan-in semiconductor package has a large spatial limitation. Therefore, it is difficult to apply this structure to a semiconductor chip having a large number of I/O terminals or a semiconductor chip having a compact size. In addition, due to the disadvantage described above, the fan-in semiconductor package may not be directly mounted and used on the main board of the electronic device. The reason is that even in the case that a size of the I/O terminals of the semiconductor chip and an interval between the I/O terminals of the semiconductor chip are increased by a redistribution process, the size of the I/O terminals of the semiconductor chip and the interval between the I/O terminals of the semiconductor chip may not be sufficient to directly mount the fan-in semiconductor package on the main board of the electronic device.

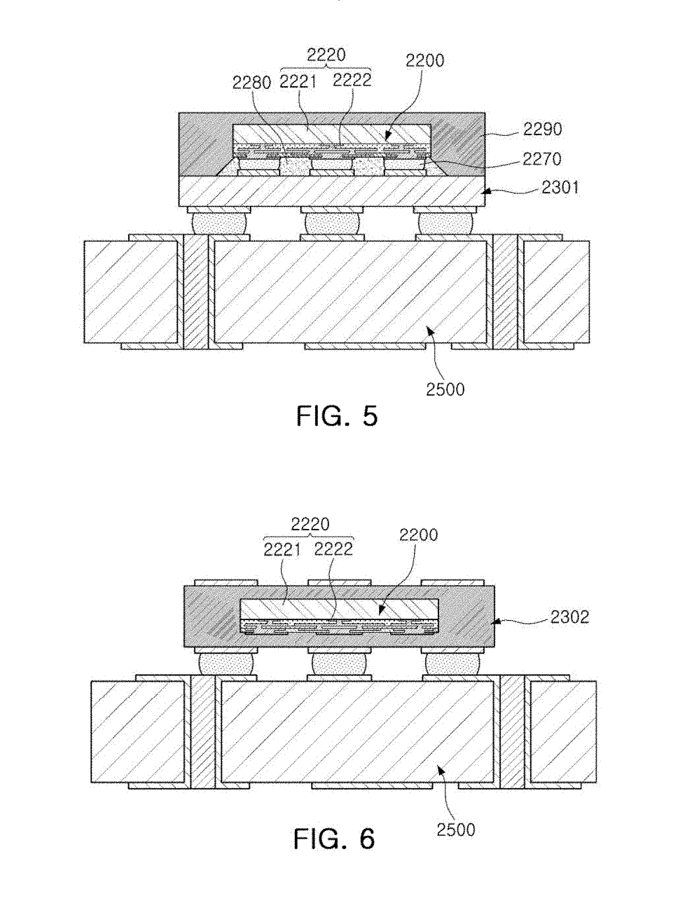

FIG. 5 is a schematic cross-sectional view illustrating a case in which a fan-in semiconductor package is mounted on an interposer substrate and is finally mounted on a main board of an electronic device.

FIG. 6 is a schematic cross-sectional view illustrating a case in which a fan-in semiconductor package is embedded in an interposer substrate and is finally mounted on a main board of an electronic device.

Referring to the drawings, in a fan-in semiconductor package 2200, connection pads 2222, that is, I/O terminals, of a semiconductor chip 2220 may be redistributed through an interposer substrate 2301, and the fan-in semiconductor package 2200 may be finally mounted on a main board 2500 of an electronic device in a state in which it is mounted on the interposer substrate 2301. In this case, solder balls 2270, and the like, may be fixed by an underfill resin 2280, or the like, and an outer side of the semiconductor chip 2220 may be covered with a molding material 2290, or the like. Alternatively, a fan-in semiconductor package 2200 may be embedded in a separate interposer substrate 2302, connection pads 2222, that is, I/O terminals, of the semiconductor chip 2220 may be redistributed by the interposer substrate 2302 in a state in which the fan-in semiconductor package 2200 is embedded in the interposer substrate 2302, and the fan-in semiconductor package 2200 may be finally mounted on a main board 2500 of an electronic device.

As described above, it may be difficult to directly mount and use the fan-in semiconductor package on the main board of the electronic device. Therefore, the fan-in semiconductor package may be mounted on the separate interposer substrate and be then mounted on the main board of the electronic device through a packaging process or may be mounted and used on the main board of the electronic device in a state in which it is embedded in the interposer substrate.

Fan-Out Semiconductor Package

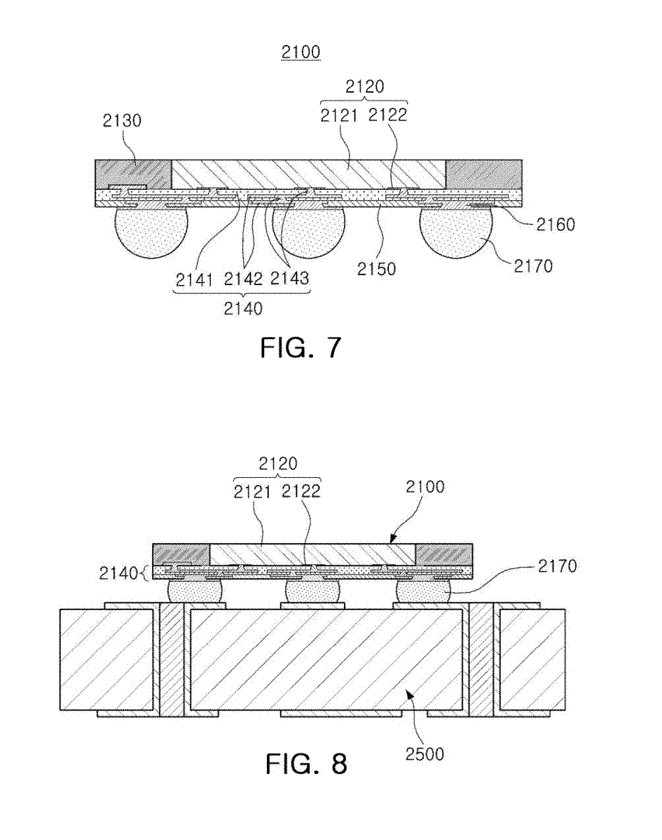

FIG. 7 is a schematic cross-sectional view illustrating a fan-out semiconductor package.

Referring to the drawing, in a fan-out semiconductor package 2100, for example, an outer side of a semiconductor chip 2120 may be protected by an encapsulant 2130, and connection pads 2122 of the semiconductor chip 2120 may be redistributed outwardly of the semiconductor chip 2120 by an interconnection member 2140. In this case, a passivation layer 2150 may be further formed on the interconnection member 2140, and an under-bump metal layer 2160 may be further formed in openings of the passivation layer 2150. Solder balls 2170 may be further formed on the under-bump metal layer 2160. The semiconductor chip 2120 may be an integrated circuit (IC) including a body 2121, the connection pads 2122, a passivation layer (not illustrated), and the like. The interconnection member 2140 may include an insulating layer 2141, redistribution layers 2142 formed on the insulating layer 2141, and vias 2143 electrically connecting the connection pads 2122 and the redistribution layers 2142 to each other.

As described above, the fan-out semiconductor package may have a form in which I/O terminals of the semiconductor chip are redistributed and disposed outwardly of the semiconductor chip through the interconnection member formed on the semiconductor chip. As described above, in the fan-in semiconductor package, all I/O terminals of the semiconductor chip need to be disposed inside the semiconductor chip. Therefore, when a size of the semiconductor chip is decreased, a size and a pitch of balls need to be decreased, such that a standardized ball layout may not be used in the fan-in semiconductor package. On the other hand, the fan-out semiconductor package has the form in which the I/O terminals of the semiconductor chip are redistributed and disposed outwardly of the semiconductor chip through the interconnection member formed on the semiconductor chip as described above. Therefore, even in the case that a size of the semiconductor chip is decreased; a standardized ball layout may be used in the fan-out semiconductor package as it is, such that the fan-out semiconductor package may be mounted on the main board of the electronic device without using a separate interposer substrate, as described below.

FIG. 8 is a schematic cross-sectional view illustrating a case in which a fan-out semiconductor package is mounted on a main board of an electronic device.

Referring to the drawing, a fan-out semiconductor package 2100 may be mounted on a main board 2500 of an electronic device through solder balls 2170, or the like. That is, as described above, the fan-out semiconductor package 2100 includes the interconnection member 2140 formed on the semiconductor chip 2120 and capable of redistributing the connection pads 2122 to a fan-out region that is outside of a size of the semiconductor chip 2120, such that the standardized ball layout may be used in the fan-out semiconductor package 2100 as it is. As a result, the fan-out semiconductor package 2100 may be mounted on the main board 2500 of the electronic device without using a separate interposer substrate, or the like.

As described above, since the fan-out semiconductor package may be mounted on the main board of the electronic device without using the separate interposer substrate, the fan-out semiconductor package may be implemented at a thickness lower than that of the fan-in semiconductor package using the interposer substrate. Therefore, the fan-out semiconductor package may be miniaturized and thinned. In addition, the fan-out semiconductor package has excellent thermal characteristics and electrical characteristics, such that it is particularly appropriate for a mobile product. Therefore, the fan-out semiconductor package may be implemented in a form more compact than that of a general package-on-package (POP) type using a printed circuit board (PCB), and may solve a problem due to occurrence of a warpage phenomenon.

Meanwhile, the fan-out semiconductor package refers to package technology for mounting the semiconductor chip on the main board of the electronic device, or the like, as described above, and protecting the semiconductor chip from external impacts, and is a concept different from that of a printed circuit board (PCB) such as an interposer substrate, or the like, having a scale, a purpose, and the like, different from those of the fan-out semiconductor package, and having the fan-in semiconductor package embedded therein.

A fan-out semiconductor package in which corrosion of a connection pad that may occur due to various causes may be prevented will hereinafter be described with reference to the drawings.

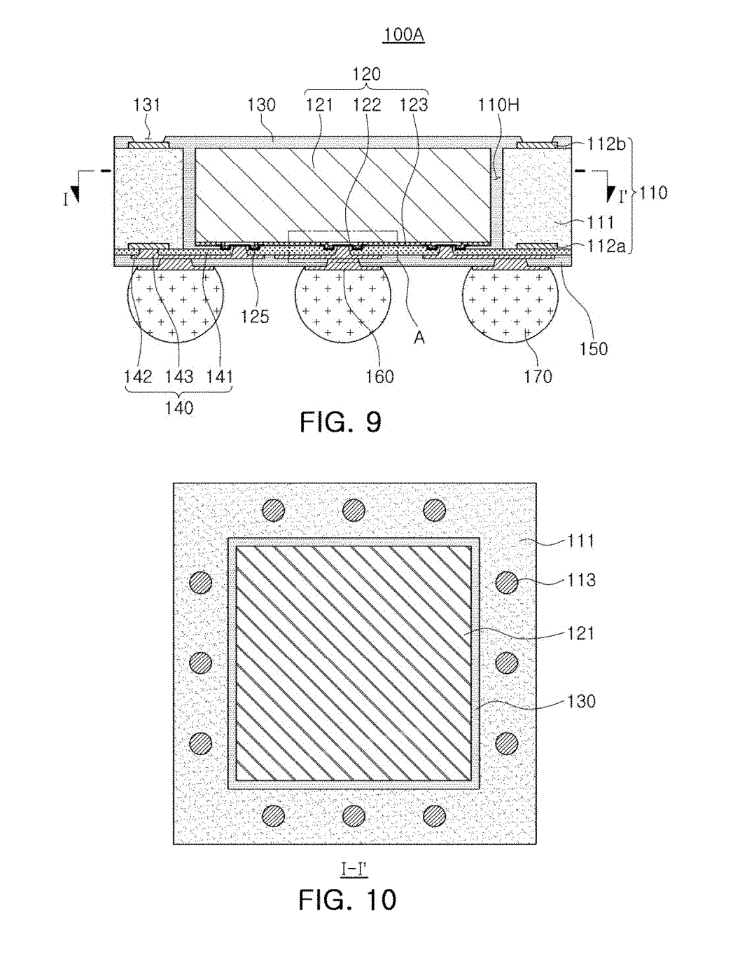

FIG. 9 is a schematic cross-sectional view illustrating an example of a fan-out semiconductor package.

FIG. 10 is a schematic plan view taken along line I-I′ of the fan-out semiconductor package of FIG. 9.

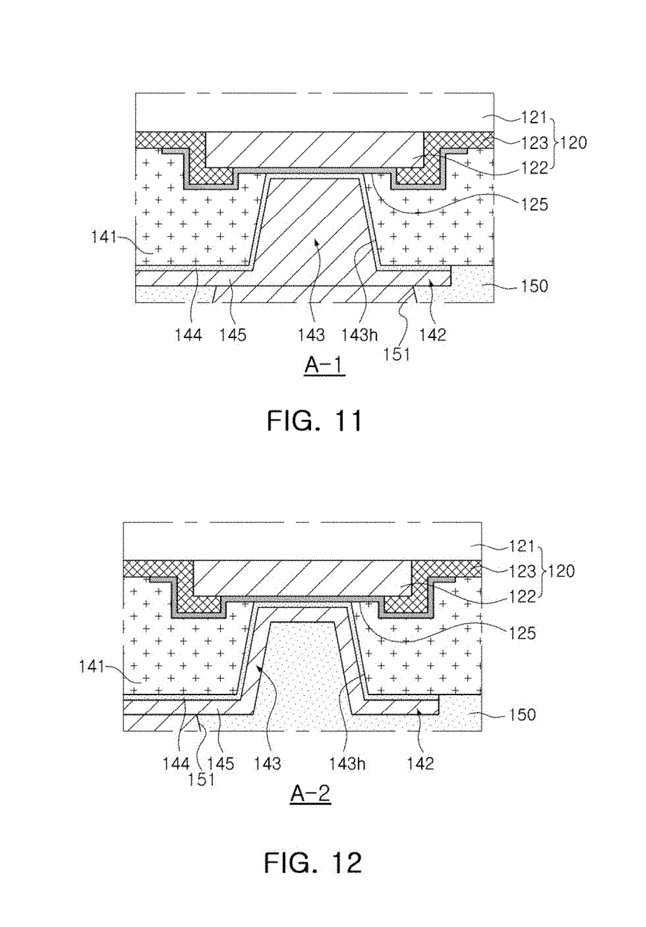

FIG. 11 is a schematic enlarged view illustrating region A of the fan-out semiconductor package of FIG. 9.

FIG. 12 is a schematic enlarged view illustrating a modified example of region A of the fan-out semiconductor package of FIG. 9.

Referring to the drawings, a fan-out semiconductor package 100A according to an exemplary embodiment in the present disclosure may include a first interconnection member 110 having a through-hole 110H, a semiconductor chip 120 disposed in the through-hole 110H of the first interconnection member 110 and having an active surface having connection pads 122 disposed thereon and an inactive surface opposing the active surface, an encapsulant 130 encapsulating at least portions of the first interconnection member 110 and the inactive surface of the semiconductor chip 120, a second interconnection member 140 disposed on the first interconnection member 110 and the active surface of the semiconductor chip 120, a passivation layer 150 disposed on the second interconnection member 140, an under-bump metal layer 160 formed to be disposed on the passivation layer 150 and disposed in openings 151 of the passivation layer 150, and connection terminals 170 disposed on the under-bump metal layer 160.

The semiconductor chip 120 may include a passivation layer 123 having openings exposing at least portions of the connection pads 122. The connection pads 122 may be connected to a redistribution layer 142 through vias 143 of the second interconnection member 140. In this case, a metal layer 125 may be disposed between the connection pad 122 and the via 143. The metal layer 125 may cover an exposed surface of the connection pad 122, a wall of the opening of the passivation layer 123, and portions of a surface of the passivation layer 123. Therefore, the exposed surface of the connection pad 122 may not directly contact an insulating layer 141 and the via 143 of the second interconnection member 140, and the passivation layer 123 may not contact the via 143.

Generally, a semiconductor package has been manufactured by a traditional packaging method of mounting a chip in which circuits are formed on a silicon wafer in a pre-process on a lead frame substrate in a post-process and then molding the chip. However, recently, fan-out packaging technology of first molding a chip and directly forming fine circuits in a region including a molding region without using a lead frame substrate has become prominent. The fan-out packaging technology refers to technology of first performing molding on the chip in a state in which connection pads of the chip are exposed to extend regions in which fine circuits and connection terminals are formed to the molding region, and may secure inputs/outputs corresponding to the number required for mounting and spaces required for intervals using inexpensive package molding. Therefore, the chip may be embedded in an ultra-miniaturized/highly-integrated expensive silicon wafer to secure connectivity to a board, the lead frame substrate is not used, such that a cost may be reduced, and a wiring distance may be shortened, such that inductance and power consumption may be reduced.

As development of fine wiring for a silicon pre-process of a semiconductor industry substantially arrives at a physical limitation, development of inexpensive chip packaging technology including a fan-out wafer level package has been accelerated due to a limitation in miniaturization of a silicon wafer and a burden of investment in extreme ultraviolet (EUV) lithography technology, which is a new exposure method. However, due to a lack of reliability of dropping and acceleration in a board mounting process caused by a concentration of stress on minute portions depending on thinness of layers formed of the respective materials, chip packaging technology has not generally been used for mass production in recent times. In order to improve the reliability in the board mounting process, an underfill method in which a space between connection terminals connecting a package and a board to each other is filled with a bonding resin after the package is mounted on the board may be considered.

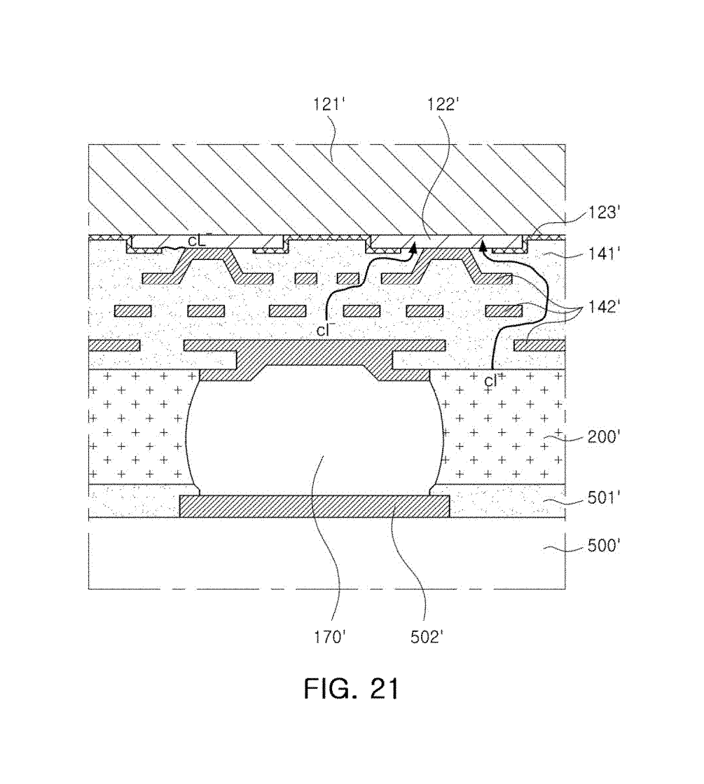

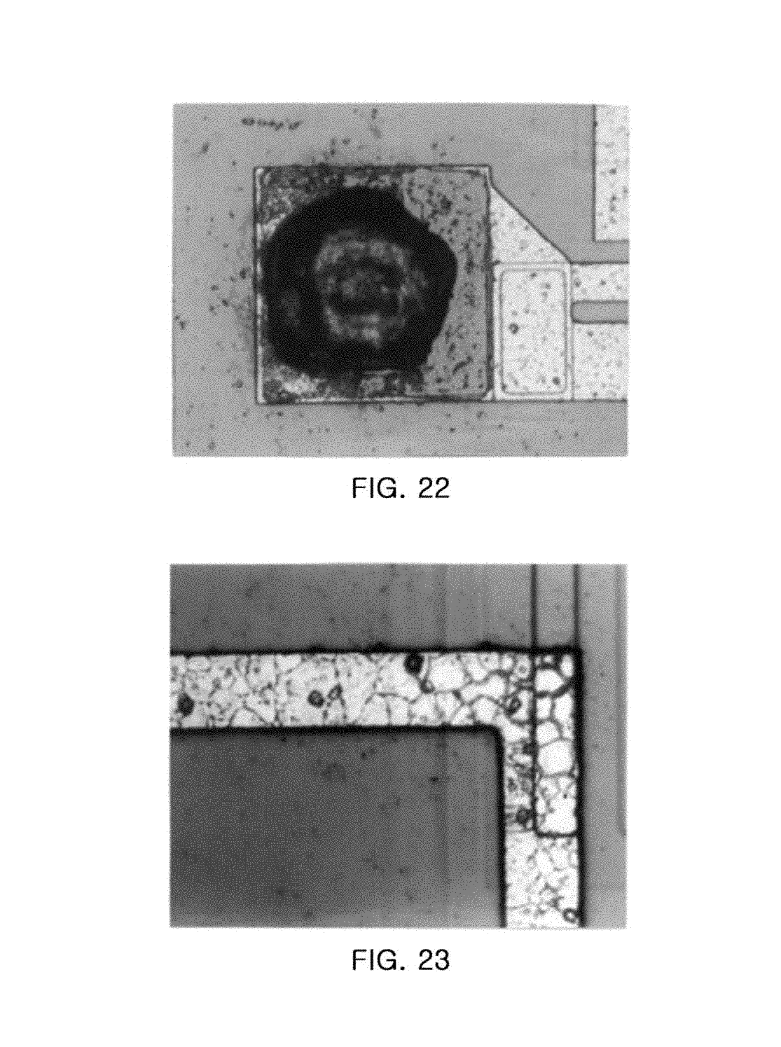

However, in the underfill method, a material that may be reworked needs to be used in order to secure a process property, and this material may include a considerable concentration or more of Cl⁻ ions. The Cl⁻ ions included in an underfill may diffuse to a polymer insulating layer 141′ in a temperature humidity bias (THB) to arrive at a connection pad 122′ of a semiconductor chip, as illustrated in FIG. 21. The Cl⁻ ions arriving at the connection pad 122′ as described above may generate corrosion of the connection pad 122′ of the semiconductor chip in both of a state in which a voltage is not applied and a state in which a voltage is applied, as illustrated in FIGS. 22 and 23. The concentration of Cl⁻ ions within the underfill may be decreased to prevent the corrosion of the connection pad due to the Cl⁻ ions. Hence, insertion of a Cl⁻ ion trap layer, addition of a dummy electrode, or the like, may be considered. However, the decrease in the concentration of the Cl⁻ ions within the underfill may deteriorate a reworking property, and the Cl⁻ ion trap layer requires an inorganic filler, such that it is difficult to insert the Cl⁻ ion trap layer into an insulating layer on which a fine pattern should be implemented. In addition, the insertion of the dummy electrode decreases only a corrosion speed of the connection pad in fact. Therefore, the insertion of the dummy electrode is not a sufficient countermeasure in securing a temperature humidity condition performed for a long time.

In order to solve the problems described above, it may be considered to forma via of a second interconnection member to cover a passivation layer, thereby blocking a path through which the connection pad is exposed to the ions. However, in this case, physical reliability such as a thermal cycle on board (TCoB), or the like, may decrease due to a structural disadvantage. For example, because it is difficult to accurately match an edge of the via and an edge of the connection pad to each other, a bonding interface between the edge of the via and the passivation layer may be generated. In this case, a relatively large amount of physical stress is applied to the edge of the via in a reliability test. Therefore, when the via contacts the passivation layer of which brittleness is relatively weaker than that of the connection pad, it is likely that a crack will be generated in the reliability test. The crack generated as described above is propagated into the via to generate an electrical open such as an interface delamination between the via and the connection pad, delamination of a layer in the connection pad, or the like, resulting in a reliability defect.

As shown in FIG. 9, in a case in which the exposed surface of the connection pad 122 is covered with the metal layer 125 having a size larger than that of the connection pad 122 in a structure in which the insulating layer 141, the redistribution layer 142, and the via 143 are directly patterned on the surface of the connection pad 122 of the semiconductor chip 120, as in the fan-out semiconductor package 100A according to the exemplary embodiment, a path through which the connection pad 122 is exposed to ions may be blocked. Therefore, a reaction of the connection pad to another ion that may generate corrosion as well as the Cl⁻ ion may be prevented. In addition, an edge of the via 143 to which high stress is applied and the passivation layer 123 of which brittleness is weak do not need to be bonded to each other, such that a risk due to generation of a crack may be reduced. In addition, an increase in a thickness of the insulating layer 141 that may increase stress of a bonding portion between the via 143 and the connection pad 122 may be suppressed, and the thickness of the insulating layer 141 may be reduced to performance and process limitations, such that a reliability risk due to the increase in the thickness may also be reduced.

The respective components included in the fan-out semiconductor package 100A according to the exemplary embodiment will hereinafter be described below in more detail.

The first interconnection member 110 may include the redistribution layers 112a and 112b redistributing the connection pads 122 of the semiconductor chip 120 to thus reduce the number of layers of the second interconnection member 140. The first interconnection member 110 may maintain rigidity of the fan-out semiconductor package 100A depending on certain materials, and serve to secure uniformity of a thickness of the encapsulant 130. In some cases, due to the first interconnection member 110, the fan-out semiconductor package 100A according to the exemplary embodiment may be used as a portion of a package-on-package. The first interconnection member 110 may have the through-hole 110H. The through-hole 110H may have the semiconductor chip 120 disposed therein to be spaced apart from the first interconnection member 110 by a predetermined distance. Side surfaces of the semiconductor chip 120 may be surrounded by the first interconnection member 110. However, such a form is only an example and may be variously modified to have other forms, and the fan-out semiconductor package 100A may perform another function depending on such a form.

The first interconnection member 110 may include an insulating layer 111 in contact with the second interconnection member 140, a first redistribution layer 112a in contact with the second interconnection member 140 and embedded in the insulating layer 111, and a second redistribution layer 112b disposed on the other surface of the insulating layer 111 opposing the surface of the insulating layer 111 in which the first redistribution layer 112a is embedded. The first interconnection member 110 may include vias 113 penetrating through the insulating layer 111 and electrically connecting the first and second redistribution layers 112a and 112b to each other. The first and second redistribution layers 112a and 112b may be electrically connected to the connection pads 122. When the first redistribution layer 112a is embedded in the insulating layer 111, a step portion generated due to a thickness of the first redistribution layer 112a may be significantly reduced, and an insulating distance of the second interconnection member 140 may thus become constant. That is, a difference between a distance from the redistribution layer 142 of the second interconnection member 140 to a lower surface of the insulating layer 111 and a distance from the redistribution layer 142 of the second interconnection member 140 to the connection pads 122 may be smaller than a thickness of the first redistribution layer 112a. Therefore, a high density wiring design of the second interconnection member 140 may be easy.

A material of the insulating layer 111 is not particularly limited. For example, an insulating material may be used as a material of the insulating layer 111. In this case, the insulating material may be a thermosetting resin such as an epoxy resin, a thermoplastic resin such as a polyimide resin, a resin in which the thermosetting resin or the thermoplastic resin is impregnated together with an inorganic filler in a core material such as a glass cloth (or a glass fabric), for example, prepreg, Ajinomoto Build up Film (ABF), FR-4, Bismaleimide Triazine (BT), or the like. Alternatively, a photoimagable dielectric (PID) resin may also be used as the insulating material.

The redistribution layers 112a and 112b may serve to redistribute the connection pads 122 of the semiconductor chip 120. A material of each of the redistribution layers 112a and 112b may be a conductive material such as copper (Cu), aluminum (Al), silver (Ag), tin (Sn), gold (Au), nickel (Ni), lead (Pb), titanium (Ti), or alloys thereof. The redistribution layers 112a and 112b may perform various functions depending on designs of their corresponding layers. For example, the redistribution layers 112a and 112b may include a ground (GND) pattern, a power (PWR) pattern, a signal (S) pattern, and the like. Here, the signal (S) pattern may include various signals except for the ground (GND) pattern, the power (PWR) pattern, and the like, such as data signals, and the like. In addition, the redistribution layers 112a and 112b may include a via pad, a connection terminal pad, and the like. As a non-restrictive example, both of the redistribution layers 112a and 112b may include a ground pattern. In this case, the number of ground patterns formed on the redistribution layers 142 of the second interconnection member 140 may be significantly reduced, such that a degree of wiring design freedom may be improved.

Surface treatment layers (not illustrated) may be further formed on portions of the redistribution layer 112b exposed from the redistribution layers 112a and 112b through openings 131 formed in the encapsulant 130, if necessary. The surface treatment layers (not illustrated) are not particularly limited as long as they are known in the related art, and may be formed by, for example, electrolytic gold plating, electroless gold plating, organic solderability preservative (OSP) or electroless tin plating, electroless silver plating, electroless nickel plating/substituted gold plating, direct immersion gold (DIG) plating, hot air solder leveling (HASL), or the like.

The vias 113 may electrically connect the redistribution layers 112a and 112b formed on different layers to each other, resulting in an electrical path in the first interconnection member 110. Each of the vias 113 may also be formed of a conductive material. Each of the vias 113 may be completely filled with the conductive material, as illustrated in FIG. 10, or the conductive material may also be formed along a wall of each of the vias 113. In addition, each of the vias 113 may have all shapes known in the related art, such as a tapered shape, a cylindrical shape, and the like.

The semiconductor chip 120 may be an integrated circuit (IC) provided in an amount of several hundreds to several millions of elements or more integrated in a single chip. The IC may be, for example, an application processor chip such as a central processor (for example, a CPU), a graphics processor (for example, a GPU), a digital signal processor, a cryptographic processor, a microprocessor, a microcontroller, or the like, but is not limited thereto. The semiconductor chip 120 may be formed on the basis of an active wafer. In this case, a base material of a body 121 may be silicon (Si), germanium (Ge), gallium arsenide (GaAs), or the like. Various circuits may be formed on the body 121. The connection pads 122 may electrically connect the semiconductor chip 120 to other components. A material of the connection pads 122 may be a conductive material such as aluminum (Al), or the like. A passivation layer 123 exposing the connection pads 122 may be formed on the body 121, and may be an oxide film formed of SiO, or the like, a nitride film formed of SiN, or the like, or a double layer of an oxide layer and a nitride layer. A lower surface of the connection pads 122 may have a step with respect to a lower surface of the encapsulant 130 through the passivation layer 123. Resultantly, a phenomenon in which the encapsulant 130 bleeds into the lower surface of the connection pads 122 may be prevented to some extent. An insulating layer (not illustrated), and the like, may also be further disposed in other required positions.

The metal layer 125 may prevent ions, or the like, from permeating into the connection pad 122 of the semiconductor chip 120, and may be disposed between the connection pad 122 of the semiconductor chip 120 and the via 143 of the second interconnection member 140. The insulating layer 141 of the second interconnection member 140 may cover at least a portion of the metal layer 125, and a hole 143h of the second interconnection member 140 may expose at least a portion of the metal layer 125. The via 143 of the second interconnection member 140 may be connected to the metal layer 125. The exposed surface of the connection pad 122 of the semiconductor chip 120 may be covered with the metal layer 125, such that the surface of the connection pad 122 may not contact the insulating layer 141 and the via 143 of the second interconnection member 140. In addition, in this structure, the passivation layer 123 of the semiconductor chip 120 may also not contact the via 143 of the second interconnection member 140. Therefore, corrosion of the connection pad 122 may be prevented through the metal layer 125 without generating a side effect such as a crack, or the like. In an example, the metal layer 125 may cover the surface of the connection pad 122 of the semiconductor chip 120, the wall of the opening of the passivation layer 123 of the semiconductor chip 120 exposing at least a portion of the surface of the connection pad 122, and portions of the surface of the passivation layer 123 of the semiconductor chip 120 to effectively prevent permeation of the ions.

The metal layer 125 may include a precious metal. The precious metal may be stable against corrosion to thus effectively prevent permeation of the ions into the connection pad 122. An example of the precious metal may include gold (Au), silver (Ag), copper (Cu), platinum (Pt), iridium (Ir), ruthenium (Ru), rhodium (Rh), palladium (Pd), osmium (Os), or the like, but is not limited thereto. The metal layer 125 may also include a metal in a passive state. The metal in a passive state refers to a metal in which a natural oxidation layer is formed at the time of being exposed to the air, and the natural oxidation layer may be stable against corrosion to effectively prevent permeation of the ions into the connection pad 122. An example of the metal in a passive state may include titanium (Ti), chromium (Cr), or the like, but is not limited thereto.

The inactive surface of the semiconductor chip 120 may be disposed on a level below an upper surface of the second redistribution layer 112b of the first interconnection member 110. For example, the inactive surface of the semiconductor chip 120 may be disposed on a level below an upper surface of the insulating layer 111 of the first interconnection member 110. A height difference between the inactive surface of the semiconductor chip 120 and the upper surface of the second redistribution layer 112b of the first interconnection member 110 may be 2 μm or more, for example, 5 μm or more. In this case, generation of cracks in corners of the inactive surface of the semiconductor chip 120 may be effectively prevented. In addition, a deviation of an insulating distance on the inactive surface of the semiconductor chip 120 in a case in which the encapsulant 130 is used may be significantly reduced.

The encapsulant 130 may protect the first interconnection member 110 and/or the semiconductor chip 120. An encapsulation form of the encapsulant 130 is not particularly limited, but may be a form in which the encapsulant 130 surrounds at least portions of the first interconnection member 110 and/or the semiconductor chip 120. For example, the encapsulant 130 may cover the first interconnection member 110 and the inactive surface of the semiconductor chip 120, and fill spaces between walls of the through-hole 110H and the side surfaces of the semiconductor chip 120. In addition, the encapsulant 130 may also fill at least a portion of a space between the passivation layer 123 of the semiconductor chip 120 and the second interconnection member 140. Meanwhile, the encapsulant 130 may fill the through-hole 110H to thus serve as an adhesive and reduce buckling of the semiconductor chip 120 depending on certain materials.

The certain materials of the encapsulant 130 are not particularly limited. For example, an insulating material may be used as the certain materials of the encapsulant 130. In this case, the insulating material may be a thermosetting resin such as an epoxy resin, a thermoplastic resin such as a polyimide resin, a resin having a reinforcing material such as an inorganic filler impregnated in the thermosetting resin and the thermoplastic resin, such as ABF, FR-4, BT, a PID resin, or the like. In addition, the known molding material such as an EMC, or the like, may also be used. Alternatively, a resin in which a thermosetting resin or a thermoplastic resin is impregnated together with an inorganic filler in a core material such as a glass cloth (or a glass fabric) may also be used as the insulating material.

The encapsulant 130 may include a plurality of layers formed of a plurality of materials. For example, a space within the through-hole 110H may be filled with a first encapsulant, and the first interconnection member 110 and the semiconductor chip 120 may be covered with a second encapsulant. Alternatively, the first encapsulant may cover the first interconnection member 110 and the semiconductor chip 120 at a predetermined thickness while filling the space within the through-hole 110H, and the second encapsulant may again cover the first encapsulant at a predetermined thickness. In addition to the form described above, various forms may be used.

The encapsulant 130 may include conductive particles in order to block electromagnetic waves, if necessary. For example, the conductive particles may be any material that may block electromagnetic waves, for example, copper (Cu), aluminum (Al), silver (Ag), tin (Sn), gold (Au), nickel (Ni), lead (Pb), titanium (Ti), a solder, or the like. However, this is only an example, and the conductive particles are not particularly limited thereto.

The second interconnection member 140 may be configured to redistribute the connection pads 122 of the semiconductor chip 120. Several tens to several hundreds of connection pads 122 having various functions may be redistributed by the second interconnection member 140, and may be physically or electrically connected to an external source through connection terminals 170 to be described below depending on the functions. The second interconnection member 140 may include the insulating layers 141, the redistribution layers 142 disposed on the insulating layers 141, and the vias 143 penetrating through the insulating layers 141 and connecting the redistribution layers 142 to each other. In the fan-out semiconductor package 100A according to the exemplary embodiment, the second interconnection member 140 may include a single layer, but may also include a plurality of layers.

An insulating material may be used as a material of the insulating layers 141. In this case, a photosensitive insulating material such as a photoimagable dielectric (PID) resin may also be used as the insulating material. In this case, the insulating layer 141 may be formed to have a smaller thickness, and a fine pitch of the via 143 may be achieved more easily. When the insulating layers 141 are multiple layers, materials of the respective insulating layers 141 may be the same as each other, and may also be different from each other, if necessary. When the insulating layers 141 are the multiple layers, the insulating layers 141 may be integrated with each other depending on a process, such that a boundary therebetween may also not be apparent.

The redistribution layers 142 may substantially serve to redistribute the connection pads 122. A material of each of the redistribution layers 142 may be a conductive material such as copper (Cu), aluminum (Al), silver (Ag), tin (Sn), gold (Au), nickel (Ni), lead (Pb), titanium (Ti), or alloys thereof. The redistribution layers 142 may perform various functions depending on designs of their corresponding layers. For example, the redistribution layers 142 may include a ground (GND) pattern, a power (PWR) pattern, a signal (S) pattern, and the like. Here, the signal (S) pattern may include various signals except for the ground (GND) pattern, the power (PWR) pattern, and the like, such as data signals, and the like. In addition, the redistribution layers 142 may include a via pad, a connection terminal pad, and the like.

Surface treatment layers (not illustrated) may be further formed on portions of the redistribution layer 142 exposed from the redistribution layers 142, if necessary. The surface treatment layers (not illustrated) are not particularly limited as long as they are known in the related art, and may be formed by, for example, electrolytic gold plating, electroless gold plating, OSP or electroless tin plating, electroless silver plating, electroless nickel plating/substituted gold plating, DIG plating, HASL, or the like.

The vias 143 may electrically connect the redistribution layers 142, the connection pads 122, or the like, formed on different layers to each other, resulting in an electrical path in the fan-out semiconductor package 100A. A material of each of the vias 143 may be a conductive material such as copper (Cu), aluminum (Al), silver (Ag), tin (Sn), gold (Au), nickel (Ni), lead (Pb), titanium (Ti), or alloys thereof. The via 143 may be completely filled with the conductive material, as illustrated in FIG. 11 or the conductive material may also be formed along a wall of the via, as illustrated in FIG. 12. In addition, the via 143 may have all shapes known in the related art, such as a tapered shape, a cylindrical shape, and the like.

Each of the redistribution layer 142 and the via 143 may include a seed layer 144 and a conductor layer 145. The seed layer 144 may be formed on a surface of the metal layer 125 exposed by a hole 143h, a wall of the hole 143h, and a surface of the insulating layer 141. The conductor layer 145 may be formed on the seed layer 144. The seed layer 144 may include a first seed layer including one or more of titanium (Ti), titanium-tungsten (Ti—W), molybdenum (Mo), chromium (Cr), nickel (Ni), and nickel-chromium (Ni—Cr) and a second seed layer disposed on the first seed layer and including the same material as that of the conductor layer 145 such as copper (Cu). The first seed layer may serve as an adhesive, and the second seed layer may serve as a basic plating layer. The conductor layer 145 may include a conductive material such as copper (Cu), aluminum (Al), silver (Ag), tin (Sn), gold (Au), nickel (Ni), lead (Pb), or alloys thereof, and may generally include copper (Cu).

Thicknesses of the redistribution layers 112a and 112b of the first interconnection member 110 may be greater than those of the redistribution layers 142 of the second interconnection member 140. Since the first interconnection member 110 may have a thickness equal to or greater than that of the semiconductor chip 120, the redistribution layers 112a and 112b formed in the first interconnection member 110 may be formed to have large sizes depending on a scale of the first interconnection member 110. On the other hand, the redistribution layers 142 of the second interconnection member 140 may be formed at sizes relatively smaller than those of the redistribution layers 112a and 112b of the first interconnection member 110 for thinness of the second interconnection member 140.

The passivation layer 150 may be configured to protect the second interconnection member 140 from external physical or chemical damage. The passivation layer 150 may have the openings 151 exposing at least portions of one of the redistribution layers 142 of the second interconnection member 140. Each of the openings 151 may expose the entirety or only a portion of a surface of the redistribution layer. In some cases, each of the openings 151 may expose a side surface of the redistribution layer 142.

A material of the passivation layer 150 is not particularly limited, and may be, for example, a photosensitive insulating material. Alternatively, a solder resist may also be used as the material of the passivation layer 150. Alternatively, an insulating resin that does not include a core material, but includes a filler, for example, ABF including an inorganic filler and an epoxy resin, or the like, may be used as the material of the passivation layer 150. A surface roughness of the passivation layer 150 may be lower as compared to a general case. When the surface roughness is low as described above, several side effects that may ensue in a circuit forming process, for example, generation of a stain on a surface, difficulty in implementing a fine circuit, and the like, may be improved.

The under-bump metal layer 160 may be additionally configured to improve connection reliability of the connection terminals 170 to improve board level reliability. The under-bump metal layer 160 may fill at least portions of the openings 151 of the passivation layer 150. The under-bump metal layer 160 may be formed by the known metallization method. The under-bump metal layer 160 may include the known metal. The under-bump metal layer 160 may be formed by forming a seed layer by electro copper plating and forming a plating layer on the seed layer by electroless copper plating.

The connection terminals 170 may be additionally configured to physically or electrically externally connect the fan-out semiconductor package 100A. For example, the fan-out semiconductor package 100A may be mounted on the main board of the electronic device through the connection terminals 170. Each of the connection terminals 170 may be formed of a conductive material, for example, a solder, or the like. However, this is only an example, and a material of each of the connection terminals 170 is not particularly limited thereto. Each of the connection terminals 170 may be a land, a ball, a pin, or the like. The connection terminals 170 may be formed as a multilayer or single layer structure. When the connection terminals 170 are formed as a multilayer structure, the connection terminals 170 may include a copper (Cu) pillar and a solder. When the connection terminals 170 are formed as a single layer structure, the connection terminals 170 may include a tin-silver solder or copper (Cu). However, this is only an example, and the connection terminals 170 are not limited thereto. The number, an interval, a disposition, or the like, of the connection terminals 170 is not particularly limited, and may be sufficiently modified by a person skilled in the art depending on design particulars. For example, the connection terminals 170 may be provided in an amount of several tens to several thousands according to the number of connection pads 122 of the semiconductor chip 120, but are not limited thereto, and may also be provided in an amount of several tens to several thousands or more or several tens to several thousands or less.

At least one of the connection terminals 170 may be disposed in a fan-out region. The fan-out region is a region except for the region in which the semiconductor chip 120 is disposed. That is, the fan-out semiconductor package 100A according to the exemplary embodiment may be a fan-out package. The fan-out package may have excellent reliability as compared to a fan-in package, may implement a plurality of input/output (I/O) terminals, and may facilitate a 3D interconnection. In addition, as compared to a ball grid array (BGA) package, a land grid array (LGA) package, or the like, the fan-out package may be mounted on an electronic device without a separate board. Thus, the fan-out package may be manufactured to have a small thickness, and may have price competitiveness.

Although not illustrated in the drawings, a metal layer may be further disposed on an inner wall of the through-hole 110H of the first interconnection member 110, if necessary. That is, the side surfaces of the semiconductor chip 120 may also be surrounded by the metal layer. Heat generated by the semiconductor chip 120 may be effectively radiated in an upward or downward direction of the fan-out semiconductor package 100A through the metal layer, and electromagnetic waves may be effectively blocked through the metal layer. In addition, if necessary, a plurality of semiconductor chips may be disposed in the through-hole 110H of the first interconnection member 110, and the number of through-holes 110H of the first interconnection member 110 may be plural and semiconductor chips may be disposed in the through-holes, respectively. In addition, separate passive components such as a condenser, an inductor, and the like, may be disposed together with the semiconductor chip in the through-hole 110H. In addition, a surface mounted component may be mounted on the passivation layer 150.

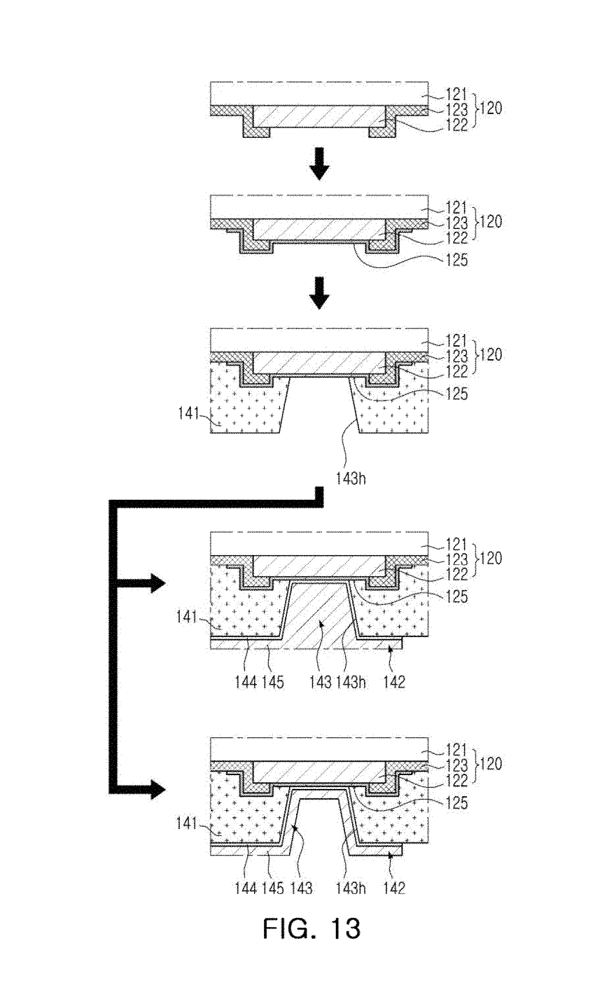

FIG. 13 is schematic views illustrating an example of processes of manufacturing region A of FIGS. 11 and 12.

Referring to the drawing, the connection pad 122 may be first formed on the active surface of the body 121, and the passivation layer 123 having the opening exposing at least a portion of the connection pad 122 may be formed on the active surface of the body 121 to prepare the semiconductor chip 120. This process may be performed on a wafer level, and may be performed by the known semiconductor process.

Next, the metal layer 125 covering the exposed surface of the connection pad 122 of the semiconductor chip 120, the wall of the opening of the passivation layer 123 of the semiconductor chip 120 exposing at least a portion of the surface of the connection pad 122, and portions of the surface of the passivation layer 123 of the semiconductor chip 120 may be formed. As described above, the metal layer 125 may be formed at a size equal to or larger than an exposure size of the connection pad 122 of the semiconductor chip 120. In this case, permeation of ions may be effectively prevented. The metal layer 125 may be formed by the known metal coating process, the metal plating process, or the like.

Next, the insulating layer 141 of the second interconnection member 140 covering the metal layer 125 may be formed on one surface of the semiconductor chip 120, and the hole 143h penetrating through the insulating layer 141 of the second interconnection member 140 and exposing at least a portion of the metal layer 125 may be formed. The insulating layer 141 may be formed by a method of laminating a precursor of the insulating layer 141 by the known lamination method and then hardening the precursor, a method of applying a precursor of the insulating layer 141 by the known application method and then hardening the precursor, or the like. The hole 143h may be formed by the known photolithography method or be formed by a mechanical drill, a laser drill, or the like, depending on a material of the insulating layer 141.

Next, the via 143 of the second interconnection member 140 may be formed in the hole 143h of the second interconnection member 140 so as to be connected to the metal layer 125, and the redistribution layer 142 may be formed on the insulating layer 141 of the second interconnection member 140 so as to be connected to the via 143. Each of the via 143 and the redistribution layer 142 may be formed by sequentially forming the seed layer 144 and the conductor layer 145. The seed layer 144 and the conductor layer 145 may be formed by the known electroplating process, the electroless plating process, or the like, and patterning may be performed using a subtractive process, an additive process, a semi-additive process (SAP), a modified semi-additive process (MSAP), or the like.

Meanwhile, although not illustrated in the drawings, the fan-out semiconductor package 100A according to the exemplary embodiment may be manufactured by forming the first interconnection member 110, disposing the semiconductor chip 120 in a face-down form in the through-hole 110H of the first interconnection member 110 using an adhesive film, or the like, encapsulating the first interconnection member 110 and the semiconductor chip 120 with the encapsulant 130, removing the adhesive film, forming the second interconnection member 140, and sequentially forming the passivation layer 150, the under-bump metal layer 160, and the connection terminals 170. The metal layer 125 may be formed before the semiconductor chip 120 is disposed in the through-hole 110H of the first interconnection member 110 or be formed after the semiconductor chip 120 is disposed in the through-hole 110H of the first interconnection member 110 and before the second interconnection member 140 is formed. Detailed processes performed in the respective processes may be performed by the known plating method, the patterning method, the lamination method, or the like, depending on the abovementioned structures.

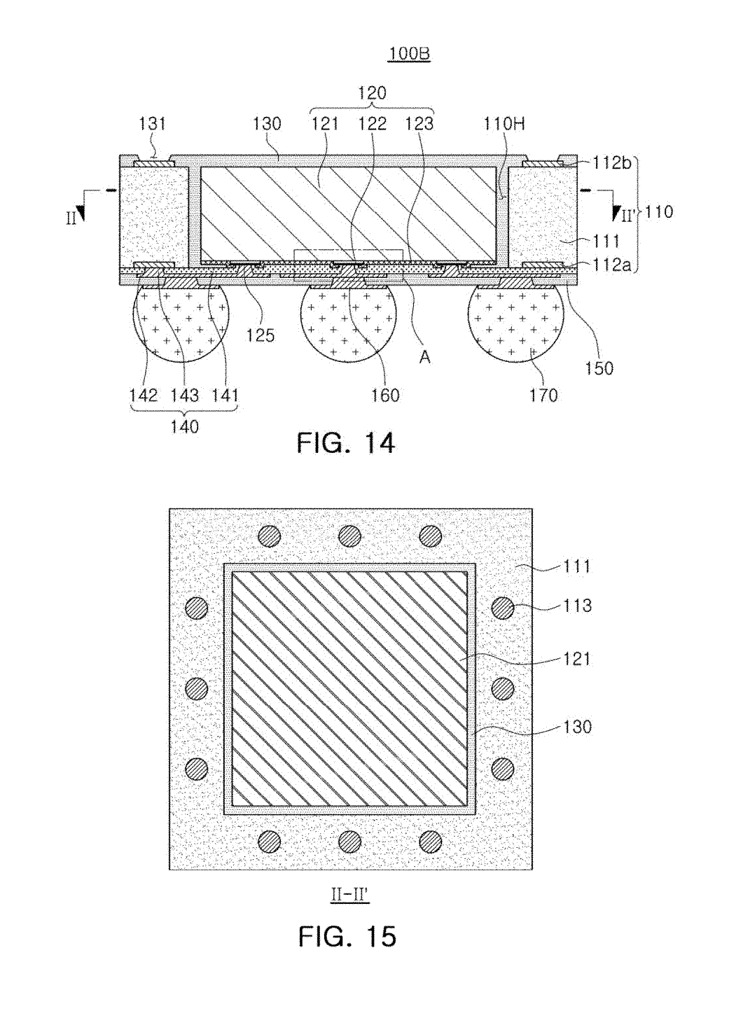

FIG. 14 is a schematic cross-sectional view illustrating another example of a fan-out semiconductor package.

FIG. 15 is a schematic plan view taken along line II-II′ of the fan-out semiconductor package of FIG. 14.

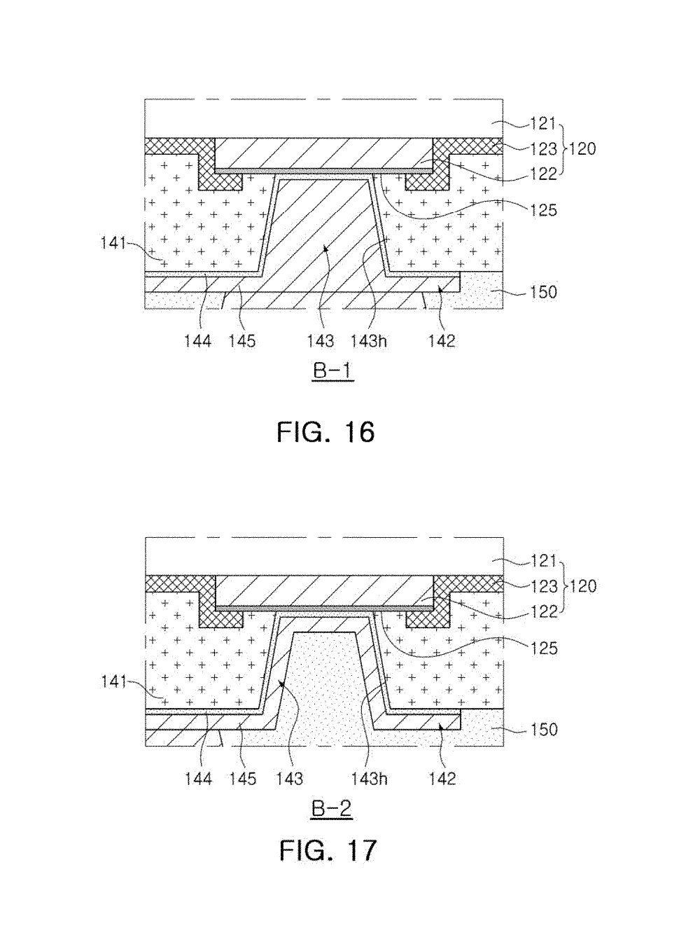

FIG. 16 is a schematic enlarged view illustrating region B of the fan-out semiconductor package of FIG. 14.

FIG. 17 is a schematic enlarged view illustrating a modified example of region B of the fan-out semiconductor package of FIG. 14.

Referring to the drawings, in a fan-out semiconductor package 100B according to another exemplary embodiment in the present disclosure, a metal layer 125 may be formed on a connection pad 122 before a passivation layer 123 of a semiconductor chip 120 is formed. Therefore, the metal layer 125 may cover both of an exposed surface and a non-exposed surface of the connection pad 122. That is, a portion of the metal layer 125 may cover the exposed surface of the connection pad 122 of the semiconductor chip 120, and the other portions of the metal layer 125 may be extended to edges of the connection pad 122 of the semiconductor chip 120 to thereby be disposed between the connection pad 122 of the semiconductor chip 120 and the passivation layer 123. That is, the passivation layer 123 may cover at least portions of the metal layer 125. In this case, permeation of ions may be effectively prevented without generating a side effect such as a crack, or the like. A description, or the like, of other configurations except for the abovementioned configuration overlaps that described above, and is thus omitted.

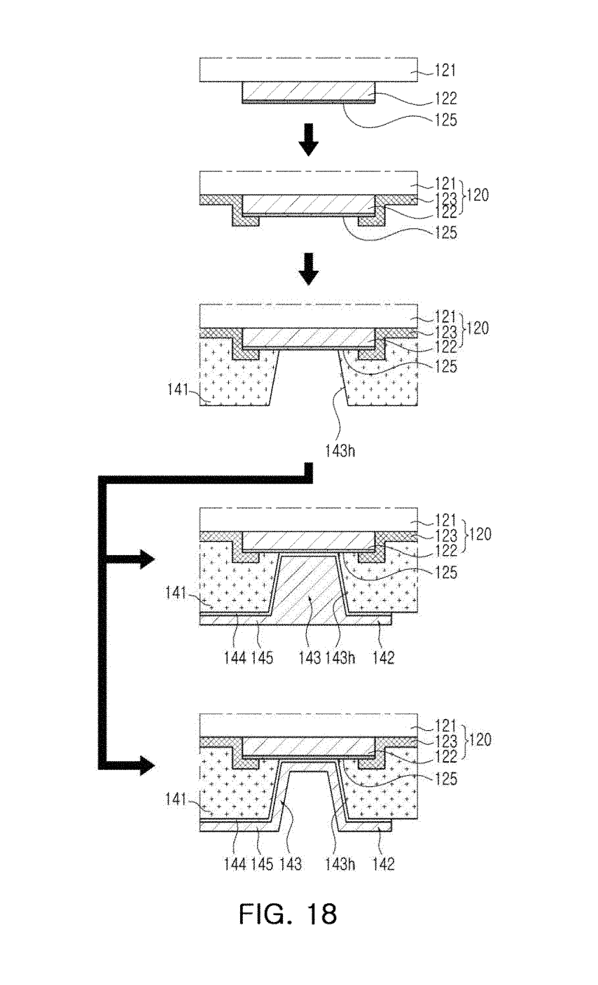

FIG. 18 is schematic views illustrating an example of processes of manufacturing region B of FIGS. 16 and 17.

Referring to the drawing, the connection pad 122 may be first formed on one surface of a body 121, and the metal layer 125 may be formed on a surface of the connection pad 122 on one surface of the body 121. Next, the passivation layer 123 covering side surfaces of the connection pad 122 and portions of edges of the metal layer 125 may be formed on one surface of the body 121. This process may be performed on a wafer level, and may be performed by the known semiconductor process. The metal layer 125 may be formed by the known coating process, the plating process, or the like. Next, an insulating layer 141 of a second interconnection member 140 covering at least portions of the metal layer 125 may be formed on one surface of the semiconductor chip 120, and a hole 143h penetrating through the insulating layer 141 of the second interconnection member 140 and exposing at least a portion of the metal layer 125 may be formed. Next, a via 143 of the second interconnection member 140 may be formed in the hole 143h of the second interconnection member 140 so as to be connected the metal layer 125, and a redistribution layer 142 may be formed on the insulating layer 141 of the second interconnection member 140 so as to be connected to the via 143. Each of the via 143 and the redistribution layer 142 may be formed by sequentially forming a seed layer 144 and a conductor layer 145. Detailed processes performed in the respective processes may be substantially the same as those described above.

Meanwhile, although not illustrated in the drawings, the fan-out semiconductor package 100B according to another exemplary embodiment may be manufactured by forming a first interconnection member 110, disposing the semiconductor chip 120 on which the metal layer 125 is formed according to the manufacturing example described above in a face-down form in a through-hole 110H of the first interconnection member 110 using an adhesive film, or the like, encapsulating the first interconnection member 110 and the semiconductor chip 120 with an encapsulant 130, removing the adhesive film, forming the second interconnection member 140 according to the manufacturing example described above, and sequentially forming a passivation layer 150, an under-bump metal layer 160, and a connection terminals 170. Detailed processes performed in the respective processes may be performed by the known plating method, the patterning method, the lamination method, or the like, depending on the abovementioned structures.

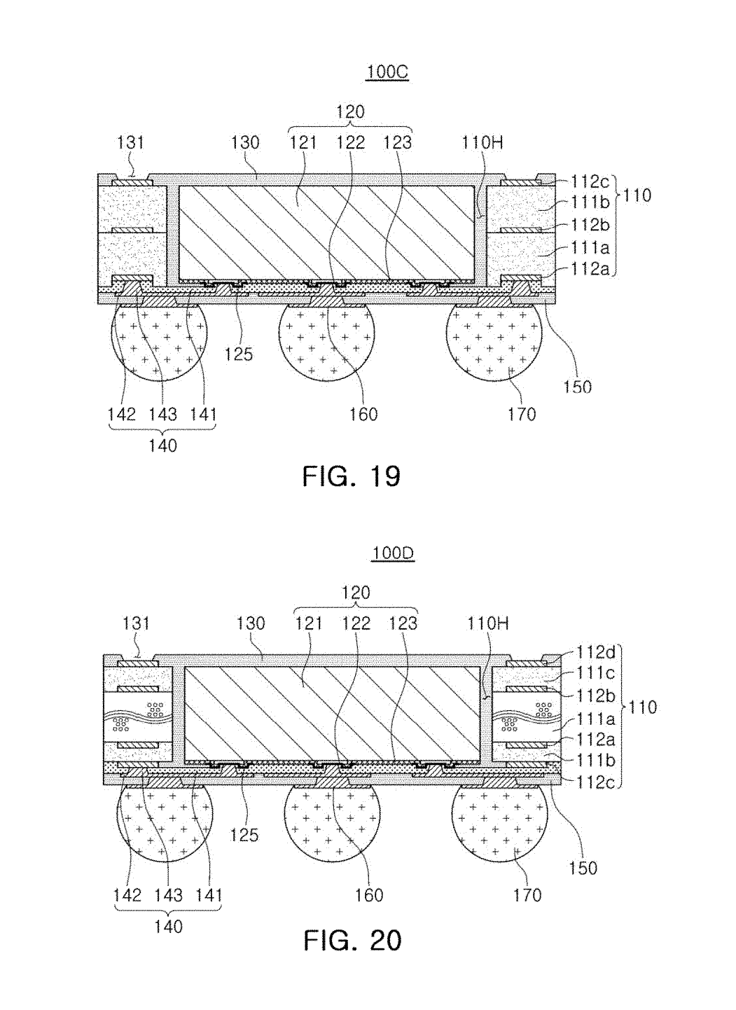

FIG. 19 is a schematic cross-sectional view illustrating another example of a fan-out semiconductor package.

Referring to the drawing, in a fan-out semiconductor package 100C according to another exemplary embodiment in the present disclosure, a first interconnection member 110 may include a first insulating layer 111a in contact with a second interconnection member 140, a first redistribution layer 112a in contact with the second interconnection member 140 and embedded in the first insulating layer 111a, a second redistribution layer 112b disposed on the other surface of the first insulating layer 111a opposing one surface of the first insulating layer 111a in which the first redistribution layer 112a is embedded, a second insulating layer 111b disposed on the first insulating layer 111a and covering the second redistribution layer 112b, and a third redistribution layer 112c disposed on the second insulating layer 111b. The first to third redistribution layers 112a, 112b, and 112c may be electrically connected to connection pads 122. Meanwhile, although not illustrated in the drawing, the first and second redistribution layers 112a and 112b and the second and third redistribution layers 112b and 112c may be electrically connected to each other through first and second vias penetrating through the first and second insulating layers 111a and 111b, respectively.

Since the first redistribution layer 112a is embedded, an insulating distance of an insulating layer 141 of the second interconnection member 140 may be substantially constant, as described above. Since the first interconnection member 110 may include a large number of redistribution layers 112a, 112b, and 112c, the second interconnection member 140 may be further simplified. Therefore, a decrease in a yield depending on a defect occurring in a process of forming the second interconnection member 140 may be improved. The first redistribution layer 112a may be recessed into the first insulating layer 111a, such that a lower surface of the first insulating layer 111a and a lower surface of the first redistribution layer 112a have a step therebetween. Resultantly, when an encapsulant 130 is formed, a phenomenon in which a material of the encapsulant 130 bleeds to pollute the first redistribution layer 112a may be prevented.

The lower surface of the first redistribution layer 112a of the first interconnection member 110 may be disposed on a level above a lower surface of the connection pads 122 of the semiconductor chip 120. In addition, a distance between a redistribution layer 142 of the second interconnection member 140 and the first redistribution layer 112a of the first interconnection member 110 may be greater than that between the redistribution layer 142 of the second interconnection member 140 and the connection pads 122 of the semiconductor chip 120. The reason is that the first redistribution layer 112a may be recessed into the insulating layer 111. The second redistribution layer 112b of the first interconnection member 110 may be disposed on a level between an active surface and an inactive surface of the semiconductor chip 120. The first interconnection member 110 may be formed at a thickness corresponding to that of the semiconductor chip 120. Therefore, the second redistribution layer 112b formed in the first interconnection member 110 may be disposed on a level between the active surface and the inactive surface of the semiconductor chip 120.

Thicknesses of the redistribution layers 112a, 112b, and 112c of the first interconnection member 110 may be greater than that of the redistribution layer 142 of the second interconnection member 140. Since the first interconnection member 110 may have a thickness equal to or greater than that of the semiconductor chip 120, the redistribution layers 112a, 112b, and 112c may be formed to have large sizes depending on a scale of the first interconnection member 110. On the other hand, the redistribution layer 142 of the second interconnection member 140 may be formed at a relatively small size for thinness.

A description, or the like, of other configurations and a manufacturing method except for the abovementioned configuration overlaps that described above, and is thus omitted. Although not illustrated in the drawing, characteristics of the fan-out semiconductor package 100B described above may also be applied to the fan-out semiconductor package 100C.

FIG. 20 is a schematic cross-sectional view illustrating another example of a fan-out semiconductor package.

Referring to the drawing, in a fan-out semiconductor package 100D according to another exemplary embodiment in the present disclosure, a first interconnection member 110 may include a first insulating layer 111a, a first redistribution layer 112a and a second redistribution layer 112b disposed on both surfaces of the first insulating layer 111a, respectively, a second insulating layer 111b disposed on the first insulating layer 111a and covering the first redistribution layer 112a, a third redistribution layer 112c disposed on the second insulating layer 111b, a third insulating layer 111c disposed on the first insulating layer 111a and covering the second redistribution layer 112b, and a fourth redistribution layer 112d disposed on the third insulating layer 111c. The first to fourth redistribution layers 112a, 112b, 112c, and 112d may be electrically connected to connection pads 122. Since the first interconnection member 110 may include a larger number of redistribution layers 112a, 112b, 112c, and 112d, the second interconnection member 140 may be further simplified. Therefore, a decrease in a yield depending on a defect occurring in a process of forming the second interconnection member 140 may be improved. Meanwhile, although not illustrated in the drawing, the first to fourth redistribution layers 112a, 112b, 112c, and 112d may be electrically connected to each other through first to third vias penetrating through the first to third insulating layers 111a, 111b, and 111c.

The first insulating layer 111a may have a thickness greater than those of the second insulating layer 111b and the third insulating layer 111c. The first insulating layer 111a may be relatively thick in order to maintain rigidity, and the second insulating layer 111b and the third insulating layer 111c may be introduced in order to form a larger number of redistribution layers 112c and 112d. The first insulating layer 111a may include an insulating material different from those of the second insulating layer 111b and the third insulating layer 111c. For example, the first insulating layer 111a may be, for example, prepreg including a core material, an inorganic filler, and an insulating resin, and the second insulating layer 111b and the third insulating layer 111c may be an ABF or a photosensitive insulating film including an inorganic filler and an insulating resin. However, the materials of the first insulating layer 111a and the second and third insulating layers 111b and 111c are not limited thereto.

A lower surface of the third redistribution layer 112c of the first interconnection member 110 may be disposed on a level below a lower surface of the connection pads 122 of the semiconductor chip 120. In addition, a distance between a redistribution layer 142 of the second interconnection member 140 and the third redistribution layer 112c of the first interconnection member 110 may be smaller than that between the redistribution layer 142 of the second interconnection member 140 and the connection pads 122 of the semiconductor chip 120. The reason is that the third redistribution layer 112c may be disposed in a protruding form on the second insulating layer 111b, resulting in contact with the second interconnection member 140. The first redistribution layer 112a and the second redistribution layer 112b of the first interconnection member 110 may be disposed on a level between an active surface and an inactive surface of the semiconductor chip 120. The first interconnection member 110 may be formed at a thickness corresponding to that of the semiconductor chip 120. Therefore, the first redistribution layer 112a and the second redistribution layer 112b formed in the first interconnection member 110 may be disposed on a level between the active surface and the inactive surface of the semiconductor chip 120.

Thicknesses of the redistribution layers 112a, 112b, 112c, and 112d of the first interconnection member 110 may be greater than that of the redistribution layer 142 of the second interconnection member 140. Since the first interconnection member 110 may have a thickness equal to or greater than that of the semiconductor chip 120, the redistribution layers 112a, 112b, 112c, and 112d may also be formed to have large sizes. On the other hand, the redistribution layer 142 of the second interconnection member 140 may be formed at a relatively small size for thinness.

A description, or the like, of other configurations and a manufacturing method except for the abovementioned configuration overlaps that described above, and is thus omitted. Although not illustrated in the drawing, characteristics of the fan-out semiconductor package 100B described above may also be applied to the fan-out semiconductor package 100D.

FIG. 21 is a schematic view illustrating a case in which corrosion occurs on a connection pad.

FIG. 22 is a schematic view illustrating corrosion of a connection pad in a state in which a voltage is not applied.

FIG. 23 is a schematic view illustrating corrosion of a connection pad in a state in which a voltage is applied.

Referring to the drawings, a semiconductor package may be mounted on a board 500′ through a connection terminal 170′. The connection terminal 170′ may be electrically connected to an electrode 502′ exposed from an insulating layer 501′ of the board 500′. The connection terminal 170′ may be electrically connected to connection pads 122′ through redistribution layers 142′ formed in a polymer insulating layer 141′. Meanwhile, the connection terminal 170′ may be fixed by an underfill 200′. In this case, in a temperature humidity bias (THB), ions such as Cl⁻, or the like, of the underfill 200′ may pass through the polymer insulating layer 141′ to corrode the connection pad 122′ of a semiconductor chip. In detail, in the THB, a surface, exposed from a passivation layer 123′ of the connection pad 122′ formed on a body 121′ of the semiconductor chip, may be corroded by the ions such as Cl⁻, or the like. That is, in a case in which the metal layer 125 is not formed unlike the fan-out semiconductor packages 100A to 100D according to the present disclosure, the connection pad of the semiconductor chip may be corroded in a state in which a voltage is not applied and/or a state in which a voltage is applied.

As set forth above, according to the exemplary embodiment in the present disclosure, a fan-out semiconductor package in which corrosion of a connection pad that may occur due to various causes may be prevented may be provided.

While exemplary embodiments have been shown and described above, it will be apparent to those skilled in the art that modifications and variations could be made without departing from the scope of the present invention as defined by the appended claims.

What is claimed is:

1. A fan-out semiconductor package comprising:
a first interconnection member having a through-hole;
a semiconductor chip disposed in the through-hole of the first interconnection member and having an active surface having connection pads disposed thereon and an inactive surface opposing the active surface;
an encapsulant encapsulating at least portions of the first interconnection member and the inactive surface of the semiconductor chip; and
a second interconnection member disposed on the first interconnection member and the active surface of the semiconductor chip,
wherein the first interconnection member and the second interconnection member each include a redistribution layer electrically connected to the connection pads,
the semiconductor chip includes a passivation layer having openings exposing at least portions of the connection pads,
the redistribution layer of the second interconnection member is connected to the connection pad through a via,
a metal layer is disposed between the connection pad and the via, and
the metal layer covers at least a portion of the connection pad.

2. The fan-out semiconductor package of claim 1, wherein the metal layer covers at least portions of the passivation layer.

3. The fan-out semiconductor package of claim 1, wherein the passivation layer covers at least portions of the metal layer.

4. The fan-out semiconductor package of claim 1, wherein the passivation layer is spaced apart from the via.

5. The fan-out semiconductor package of claim 1, wherein the metal layer includes one or more of gold (Au), silver (Ag), copper (Cu), platinum (Pt), iridium (Ir), ruthenium (Ru), rhodium (Rh), palladium (Pd), and osmium (Os).

6. The fan-out semiconductor package of claim 1, wherein the metal layer includes one or more of chromium and titanium.

7. The fan-out semiconductor package of claim 1, wherein the first interconnection member includes a first insulating layer, a first redistribution layer in contact with the second interconnection member and embedded in the first insulating layer, and a second redistribution layer disposed on the other surface of the first insulating layer opposing one surface of the first insulating layer in which the first redistribution layer is embedded, and
the first and second redistribution layers are electrically connected to the connection pads.

8. The fan-out semiconductor package of claim 7, wherein the first interconnection member further includes a second insulating layer disposed on the first insulating layer and covering the second redistribution layer and a third redistribution layer disposed on the second insulating layer, and
the third redistribution layer is electrically connected to the connection pads.

9. The fan-out semiconductor package of claim 7, wherein a distance between the redistribution layer of the second interconnection member and the first redistribution layer is greater than that between the redistribution layer of the second interconnection member and the connection pads.

10. The fan-out semiconductor package of claim 7, wherein the first redistribution layer has a thickness greater than that of the redistribution layer of the second interconnection member.

11. The fan-out semiconductor package of claim 7, wherein a lower surface of the first redistribution layer is disposed on a level above a lower surface of the connection pads.

12. The fan-out semiconductor package of claim 8, wherein the second redistribution layer is disposed on a level between the active surface and the inactive surface of the semiconductor chip.

13. The fan-out semiconductor package of claim 1, wherein the first interconnection member includes a first insulating layer, a first redistribution layer and a second redistribution layer disposed on both surfaces of the first insulating layer, respectively, a second insulating layer disposed on the first insulating layer and covering the first redistribution layer, and a third redistribution layer disposed on the second insulating layer, and
the first, second and third redistribution layers are electrically connected to the connection pads.

14. The fan-out semiconductor package of claim 13, wherein the first interconnection member further includes a third insulating layer disposed on the first insulating layer and covering the second redistribution layer and a fourth redistribution layer disposed on the third insulating layer, and
the fourth redistribution layer is electrically connected to the connection pads.

15. The fan-out semiconductor package of claim 13, wherein the first insulating layer has a thickness greater than that of the second insulating layer.

16. The fan-out semiconductor package of claim 13, wherein the third redistribution layer has a thickness greater than that of the redistribution layer of the second interconnection member.

17. The fan-out semiconductor package of claim 13, wherein the first redistribution layer is disposed on a level between the active surface and the inactive surface of the semiconductor chip.

18. The fan-out semiconductor package of claim 13, wherein a lower surface of the third redistribution layer is disposed on a level below a lower surface of the connection pads.
